(19) United States
(12) Patent Application Publication
(10) Pub. No.: US 2026/0269198 A1
(43) Pub. Date: Sep. 10, 2026

(54) APPARATUS AND METHOD FOR CLEANING SUSCEPTORS WITH PLASMA

(71) Applicant: Applied Materials, Inc., Santa Clara, CA (US)

(72) Inventors: THAI CHENG CHUA, Cupertino, CA (US); MARCUS HERNANDEZ, Santa Clara, CA (US); HAO-CHUN KAO, San Ramon, CA (US); ADAM FISCHBACH, Campbell, CA (US); CHRISTIAN VALENCIA, Alhambra, CA (US); RUSSELL CHIN YEE TEO, Palo Alto, CA (US)

(21) Appl. No.: 19/070,247

(22) Filed: Mar. 4, 2025

(51) Int. Cl. H01J 37/32

(52) U.S. Cl. CPC H01J 37/32862; H01J 37/32247; H01J 37/32651; H01J 37/32899

(57) ABSTRACT

Embodiments described herein relate to an apparatus that includes a chamber, and a lid that is configured to seal the chamber. In an embodiment, the lid includes a dielectric faceplate, and a plurality of dielectric resonators coupled to the dielectric faceplate. In an embodiment, the plurality of dielectric resonators are arranged in a ring-like pattern. In an embodiment, a gas line passes through the lid, and the gas line is within an inner perimeter of the ring-like pattern.

### BACKGROUND

### 1) Field

Embodiments relate to the field of semiconductor manufacturing and, in particular, systems that may be used to clean parasitic layers from the surface of susceptors.

### 2) Description of Related Art

In some semiconductor processing operations, a substrate (such as a semiconductor wafer) is retained in a susceptor. The susceptor may include a recess for supporting the substrate so that a top surface of the substrate is substantially coplanar with a top surface of the susceptor. During deposition processes, the layer that is deposited may also deposit on surfaces of the susceptor. This additional deposition may sometimes be referred to as being parasitic deposition.

The parasitic deposition along the edges of the susceptor may result in issues when subsequent substrates are processed on the susceptor. For example, contamination from re-deposition of materials back onto the substrate may occur. The parasitic deposition may also be prone to particle generation. Elements of the parasitic deposition may also diffuse into the substrate to generate unwanted doping of the substrate.

Accordingly, the parasitic deposition needs to be removed and/or cleaned on a regular basis. Current industry practice is to either discard the susceptor after a certain number of substrates have been processed, or the susceptor is manually cleaned by scaping off the parasitic deposition. With either approach, the chamber needs to be opened to replace the susceptor. This can lead to significant down time for the chamber.

### SUMMARY

Embodiments described herein relate to an apparatus that includes a chamber, and a lid that is configured to seal the chamber. In an embodiment, the lid includes a dielectric faceplate, and a plurality of dielectric resonators coupled to the dielectric faceplate. In an embodiment, the plurality of dielectric resonators are arranged in a ring-like pattern. In an embodiment, a gas line passes through the lid, and the gas line is within an inner perimeter of the ring-like pattern.

Embodiments described herein relate to a semiconductor processing tool that includes a transfer chamber and a first chamber coupled to the transfer chamber. In an embodiment, the first chamber is configured to deposit a layer on a substrate that is supported by a susceptor. In an embodiment, a second chamber is coupled to the transfer chamber, and the second chamber is configured to clean the susceptor with a plasma that is localized over an outer region of the susceptor.

Embodiments described herein relate to a chamber lid that includes a dielectric faceplate with a plurality of openings, where the plurality of openings are arranged in a ring-like pattern. In an embodiment, a shield is on a surface of the dielectric faceplate, and the shield has an outer surface that is inside the ring-like pattern. In an embodiment, a gas line passes through the dielectric faceplate, and the gas line is inside an outer perimeter of the shield.

### BRIEF DESCRIPTION OF THE DRAWINGS

FIG. 1A is a perspective view illustration of a susceptor, in accordance with an embodiment.

FIG. 1B is a perspective view illustration of a susceptor that is holding a substrate, in accordance with an embodiment.

FIG. 2A-2C are cross-sectional illustrations depicting the deposition of a layer over the substrate and the susceptor, in accordance with an embodiment.

FIG. 3A is a cross-sectional illustration of a chamber with a lid that includes a faceplate and shield for selectively forming a plasma around an outer edge of a susceptor, in accordance with an embodiment.

FIG. 3B is a cross-sectional illustration of a chamber with a lid that includes a faceplate and cylindrical shield for selectively forming a plasma around an outer edge of a susceptor, in accordance with an embodiment.

FIG. 3C is a cross-sectional illustration of a chamber with a lid that includes a faceplate and gas flow conditions for selectively forming a plasma around an outer edge of a susceptor, in accordance with an embodiment.

FIG. 4A is a plan view illustration of a faceplate of a lid that includes a shield, a plurality of dielectric resonators, and a plurality of optical ports, in accordance with an embodiment.

FIG. 4B is a cross-sectional illustration of a chamber with a lid that includes an optical port that enables real-time optical endpoint detection for an etching process in the chamber, in accordance with an embodiment.

FIG. 5 is a plan view illustration of a cluster tool that includes a plurality of chambers where at least one of the chambers is a susceptor cleaning chamber, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include systems that may be used to clean parasitic layers from the surface of susceptors. In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, some semiconductor processing operations include placing a substrate on a susceptor during the processing. In the case of a deposition process, such as a chemical vapor deposition (CVD), atomic layer deposition (ALD), physical vapor deposition (PVD), or the like, the deposited layer may also be deposited on the outer edge of the susceptor as parasitic deposition. After the processing of multiple substrates, the parasitic deposition on the susceptor may lead to issues during future deposition processes. For example, problems with re-deposition of material onto the substrate, auto-doping the substrate, particle generation, and/or the like may occur.

Instead of opening up the chamber to replace the susceptor, embodiments disclosed herein include a chamber that can be used to selectively clean the parasitic deposition on the susceptor. Particularly, the use of a modular microwave plasma source with certain chamber architectures allows for the outer edges of the susceptor to be cleaned in a low temperature environment (e.g., approximately 500° C. or less). Further, the plasma is selectively formed over the outer region of the susceptor so that the recessed region (that was protected by the substrate and does not have parasitic deposition) is protected from further etching. In this way, the value of the tool can be increased since chambers do not need to be taken offline in order to clean and/or replace the susceptor.

In some embodiments, the chamber includes a plurality of dielectric resonators that are each electrically coupled to microwave power sources. The plurality of dielectric resonators may be arranged in a ring-like pattern. A shield may be provided inside of the ring-like pattern. That is, an outer edge of the shield may be inside or within an inner perimeter of the ring-like pattern. The shield may be a ring or a substantially solid cylinder. A central gas purge line may pass through the lid in order to provide an inert gas that flows out towards edges of the susceptor in order to further mitigate the formation of plasma at a center of the chamber. In order to improve etch uniformity, the susceptor may be on a pedestal that is rotatable.

In some embodiments, the susceptor cleaning chamber may be part of a cluster tool. The cluster tool may include one or more deposition chambers (e.g., a CVD chamber, an ALD chamber, a PVD chamber, and/or the like). The one or more deposition chambers may be used to deposit layers on a substrate that is supported by a susceptor. Periodically, the susceptor may be moved into the cleaning chamber (e.g., through a transfer chamber that is coupled to the deposition chamber and the cleaning chamber). Once in the cleaning chamber, the parasitic deposition may be removed with a low temperature plasma cleaning process.

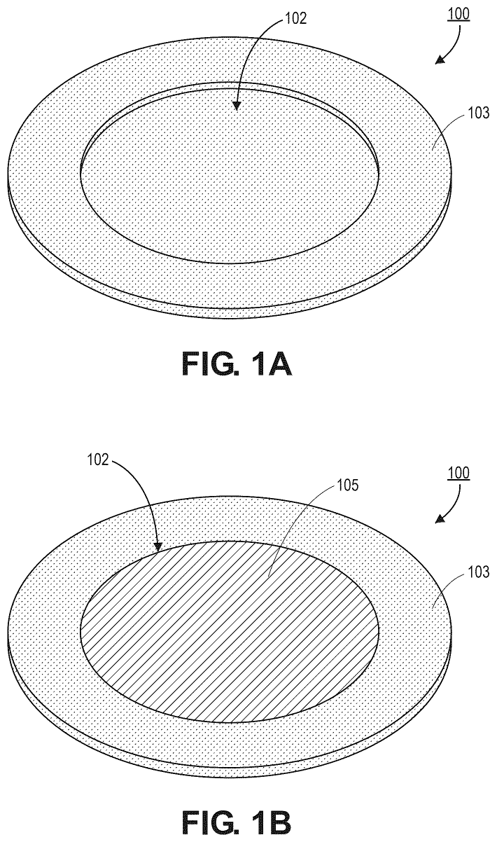

Referring now to FIG. 1A, a perspective view illustration of a susceptor 100 is shown, in accordance with an embodiment. In an embodiment, the susceptor 100 may include an outer region 103. A recess 102 may be provided at a center of the susceptor 100. The recess 102 may have a depth that allows for a substrate (not shown in FIG. 1A) to be set on the susceptor 100 so that a top surface of the substrate is substantially coplanar with the top surface of the outer region 103. The recess 102 may be sized to substantially match a form factor of the substrate. Though, the recess 102 may have a diameter that is slightly larger than a diameter of the substrate. In an embodiment, the susceptor 100 may be any suitable material or materials. In a particular embodiment, the susceptor 100 may comprise comprise a polysilicon material.

Referring now to FIG. 1B, a perspective view illustration of a susceptor 100 that includes a substrate 105 set into the recess 102 is shown, in accordance with an embodiment. As shown, the substrate 105 may have a form factor that substantially fills the recess 102. Though, the diameter of the substrate 105 may be slightly smaller than a diameter of the recess 102. In an embodiment, the substrate 105 may be any substrate used in electronics and/or semiconductor manufacturing. For example, the substrate 105 may include a semiconductor wafer, such as a silicon wafer or the like.

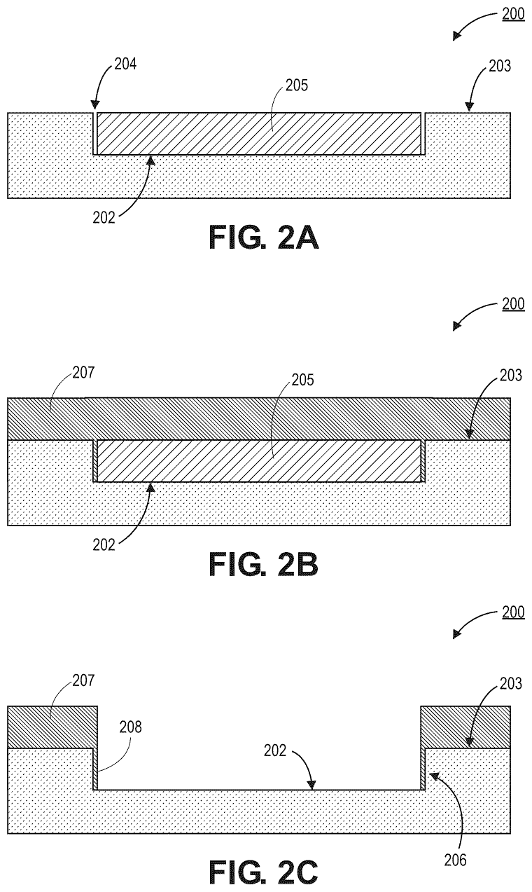

Referring now to FIG. 2A-2C, a series of cross-sectional illustrations that illustrate a process for depositing a layer over a substrate 205 and a susceptor 200 is shown, in accordance with an embodiment. In an embodiment, FIG. 2A shows a susceptor 200 with a substrate 205 set into the recess 202. In an embodiment, the substrate 205 may have a top surface that is substantially coplanar with a top surface of the outer region 203. In an embodiment, a gap 204 may be provided between an edge of the recess 202 and a sidewall of the substrate 205. In an embodiment, the susceptor 200 and the substrate 205 may be similar to the susceptor 100 and the substrate 105 described in greater detail above.

Referring now to FIG. 2B, a cross-sectional illustration of the susceptor 200 and the substrate 205 after a layer 207 is deposited over the top surfaces of the substrate 205 and the susceptor 200 is shown, in accordance with an embodiment. In an embodiment, the layer 207 may be deposited with any suitable deposition process, such as CVD, ALD, PVD, or the like. While shown as a single monolithic layer, the layer 207 may comprise one or more layers 207 with different materials. In a particular embodiment, the layer 207 is an epitaxially grown layer, such as an epitaxial silicon-carbide layer. Since the susceptor 200 also comprises silicon (e.g., polysilicon) in some embodiments, the layer 207 may also grow up from the outer region 203 of the susceptor 200. Additionally, the layer 207 may grow in the gap 204 between the substrate 205 and the edge of the recess 202.

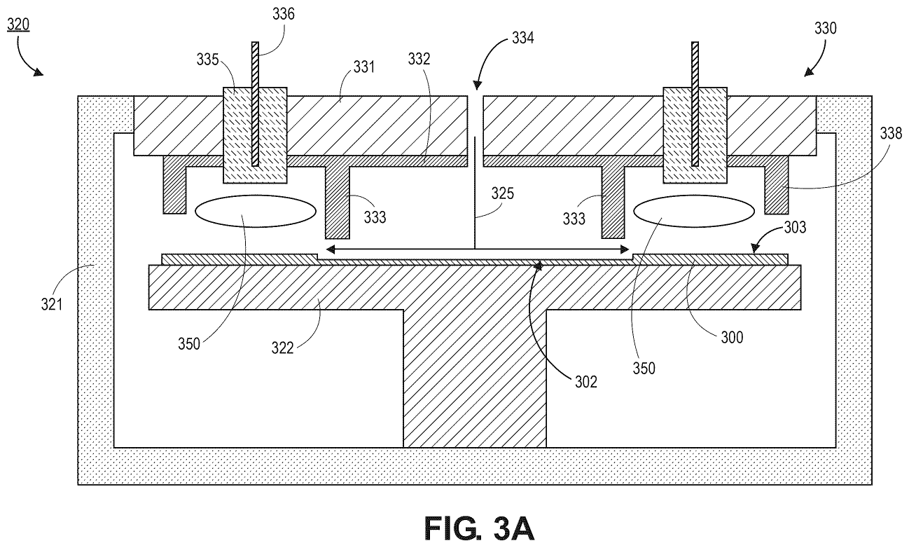

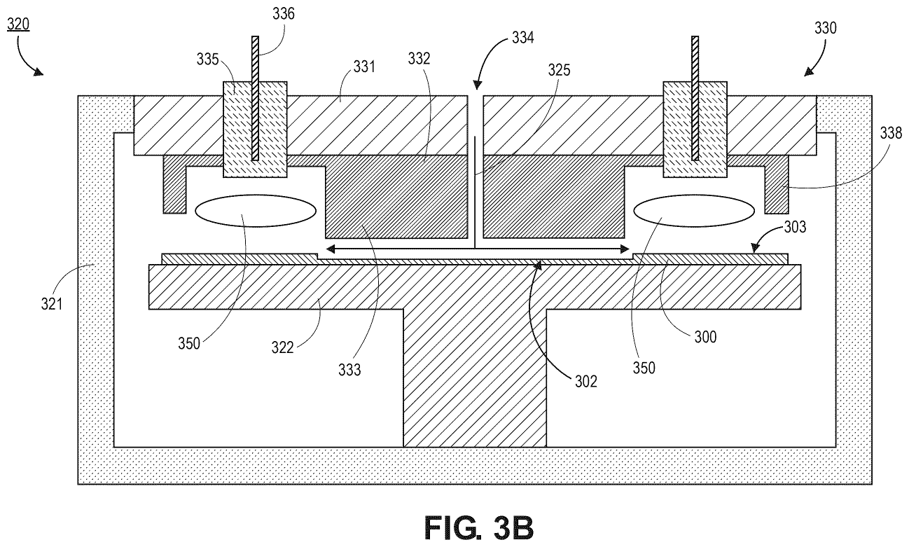

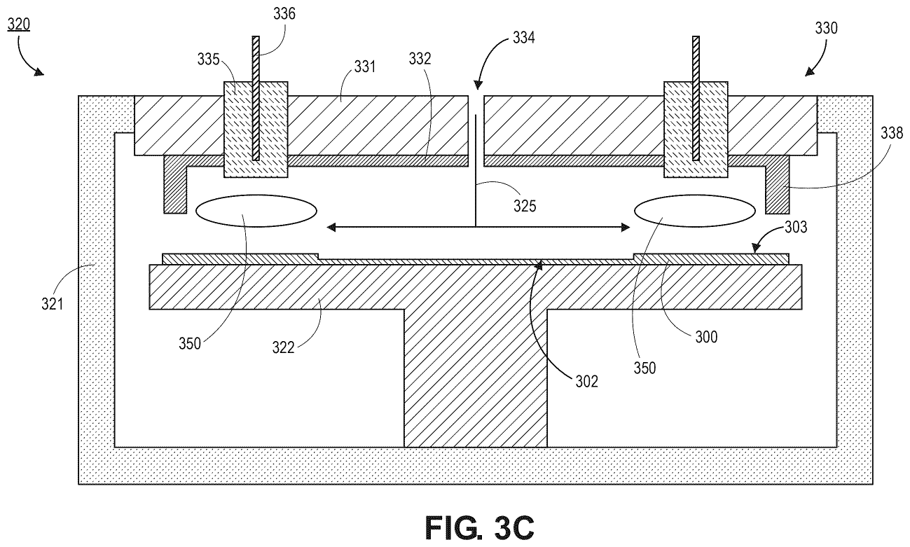

Referring now to FIG. 2C, a cross-sectional illustration of the susceptor 200 after the substrate 205 is removed is shown, in accordance with an embodiment. As shown, the majority of the recess 202 remains uncovered by the layer 207 since the substrate 205 covered the surface of the recess 202 during the deposition of the layer 207. In an embodiment, a portion 208 of the layer 207 may also cover the edge surface 206 of the recess 202. As noted above, when the layer 207 gets too thick (e.g., after a plurality of deposition cycles on a plurality of substrates 205), the layer 207 needs to be removed from the susceptor 200. The layer 207 may be removed with an etching process that is selective to the outer region 203 of the susceptor 200 so that the exposed portion of the recess 202 is not damaged. Examples of different chambers that may be used to selectively remove the layer 207 from the susceptor 200 are shown in FIG. 3A-3C.

Referring now to FIG. 3A, a cross-sectional illustration of a plasma cleaning tool 320 is shown, in accordance with an embodiment. In an embodiment, the plasma cleaning tool 320 may comprise a chamber 321 that is sealed by a lid 330. In an embodiment, the chamber 321 may be suitable for supporting a sub-atmospheric pressure, and may be commonly referred to as a vacuum chamber. A pedestal 322 may be provided in the chamber 321. The pedestal 322 may support a susceptor 300. The susceptor 300 may be similar to any of the susceptors described in greater detail herein. For example, the susceptor 300 may comprise an outer region 303 and a recess 302. In some embodiments, the pedestal 322 may be rotatable in order to rotate the susceptor 300 through the chamber 321 in order to provide a more uniform etching of the parasitic deposition (not shown in FIG. 3A).

In an embodiment, the lid 330 may be configured to generate a plasma 350 that is located primarily over the outer region 303 of the susceptor 300. In an embodiment, the lid 330 may comprise a plate 331 with a faceplate 332 on the interior surface of the plate 331. The plate 331 may comprise aluminum or the like. In an embodiment, the faceplate 332 comprises a dielectric material. The dielectric material may be a ceramic material that is compatible with plasma processes. For example, the dielectric material may comprise aluminum and oxygen (e.g., Al₂O₃). In FIG. 3A, the plate 331 is exposed to an interior of the chamber 321. Though, it is to be appreciated that the plate 331 may be shielded from the chamber interior and plasma 350 by a dielectric layer (e.g., either a part of the plate 331 or another dielectric component). For example, an outer ring 338 may continue around the exposed edges of the plate 331.

In an embodiment, the plasma 350 is preferentially formed around the outer perimeter of the chamber 321 through the use a plurality of dielectric resonators 335. In an embodiment, the dielectric resonators 335 may be sized to resonate in response to a desired frequency of electromagnetic radiation. For example, a monopole conductor 336 is inserted into each of the dielectric resonators 335. The monopole conductors 336 may each be electrically coupled to different microwave power sources. The microwave power may be coupled into processing gasses within the chamber 321 in order to generate the plasma 350. The processing gasses may be delivered into the chamber through gas distribution paths (not shown) that provide the one or more processing gasses into the outer perimeter of the chamber 321 over the outer regions 303 of the susceptor 300. Suitable processing gasses may include one or more of NF₃, Cl₂, O₂, Ar, or the like.

In an embodiment, the dielectric resonators 335 may extend through the lid 330 so that a portion of the dielectric resonators 335 are exposed to the interior of the chamber 321. For example, the dielectric resonators 335 may pass through holes in the plate 331, or the dielectric resonators 335 may pass through holes in the plate 331 and the faceplate 332. In an embodiment, a plurality of dielectric resonators 335 may be arranged in a ring-like pattern around the perimeter of the chamber 321. A ring-like pattern may refer to an arrangement of the dielectric resonators 335 such that a circle could be drawn that passes through at least a portion of each of the dielectric resonators 335. In some instances, a ring-like pattern may refer to an arrangement of dielectric resonators 335 where the longitudinal axes of each of each of the dielectric resonators 335 contact a single circle.

In an embodiment, the plasma 350 may be further confined to the outer edges of the susceptor 300 over the outer regions 303 by a shield 333. In an embodiment, the shield 333 may extend down from the faceplate 332. The shield 333 may be a ring. In an embodiment, the shield 333 may be inside an outer edge of the recess 302. Though, the shield 333 may also be outside of the recess 302. In an embodiment, a sidewall of the shield 333 may be within approximately 10 mm of an edge of the recess 302 of the susceptor 300.

In order to further reduce the chance of striking a plasma 350 over the recess 302 of the susceptor 300, a positive pressure of inert gas 325 may be flown into the chamber 321 over the recess 302 of the susceptor 300. For example, a gas distribution hole 334 (which may sometimes be referred to as a purge line) may pass through the plate 331 and the faceplate 332 in order to deliver the inert gas 325 into the chamber. As indicated by the arrows, the positive pressure extends out past the shield 333 in order to resist the formation of the plasma within the center of the chamber 321. While a single gas distribution hole 334 is shown in FIG. 3A, embodiments may also include a plurality of gas distribution holes 334. For example, a gas distribution shower head may be used to flow the inert gas 325 into the chamber 321.

In an embodiment, the positioning of the pedestal 322 may be used to control the location of the plasma 350 as well. For example, raising the pedestal 322 so that the susceptor 300 is closer to the shield 333 reduces the spread of the plasma 350 over the recess 302. However, in some instances, the sidewall of the recess 302 may need cleaning. In such an embodiment, the pedestal 322 may be lowered to allow the plasma 350 to spread in order to etch the sidewall of the recess 302. As noted above, the pedestal 322 may be rotatable in order to provide a more uniform etching of the parasitic deposition on the outer region 303 of the susceptor 300.

Referring now to FIG. 3B, a cross-sectional illustration of a plasma cleaning tool 320 is shown, in accordance with an additional embodiment. In an embodiment, the plasma cleaning tool 320 in FIG. 3B may be similar to the plasma cleaning tool 320 in FIG. 3A with the exception of the shield 333. Instead of providing a shield 333 that is a ring, the shield 333 is a cylindrical extension from the faceplate 332. Providing a shield 333 with more volume decreases volume where plasma 350 may be formed. Increasing the volume of the shield 333 may allow for a decrease in the flow rate of the gas 325 through the gas distribution hole 334.

Referring now to FIG. 3C, a cross-sectional illustration of a plasma cleaning tool 320 is shown, in accordance with an additional embodiment. In an embodiment, the plasma cleaning tool 320 in FIG. 3C may be similar to the plasma cleaning tool 320 in FIG. 3A with the exception of the shield 333. In an embodiment, the shield 333 is omitted from the lid 330 in FIG. 3C. In some embodiments, the configuration of the tool 320 may optimized to maintain the selective generation of the plasma 350 over the outer region 303 of the susceptor 300. For example, a higher flow rate of the gas 325 may be used to provide a higher positive pressure over the recess 302. In some embodiments, the pedestal 322 may be raised closer to the faceplate 332 in order to decrease the volume over the recess 302 of the susceptor 300. As such, the plasma 350 may be well confined even without the presence of a physical shield 333.

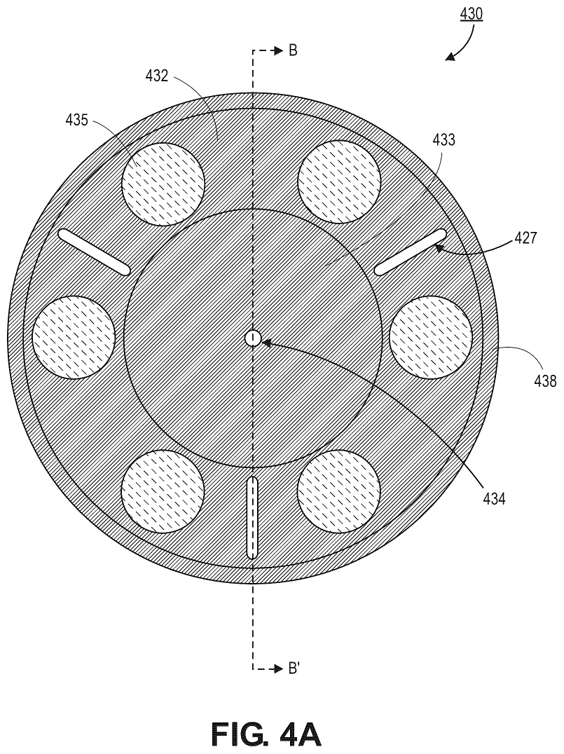

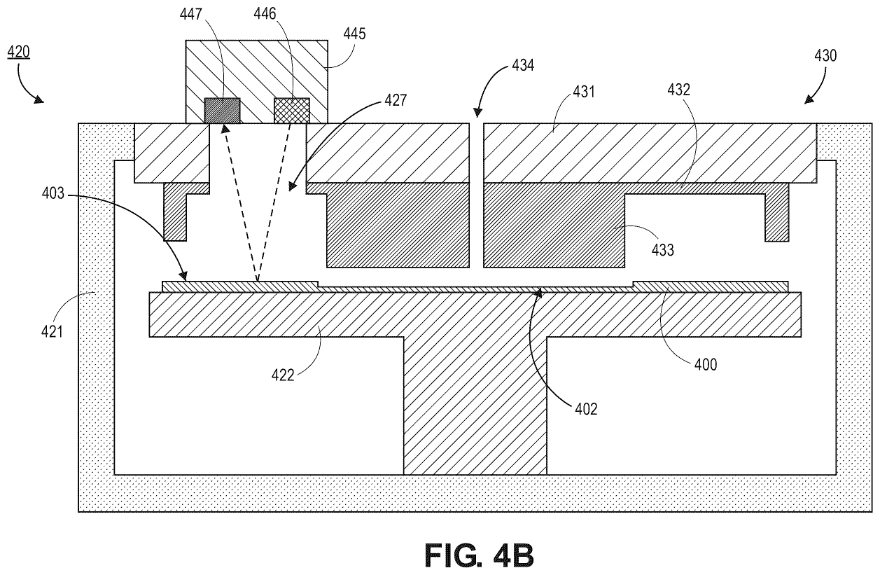

Referring now to FIG. 4A, a plan view illustration of a lid 430 for a plasma chamber is shown, in accordance with an embodiment. In an embodiment, the lid 430 may comprise a faceplate 432. In an embodiment, the faceplate 432 may be a dielectric faceplate 432 that is exposed to an interior of the chamber. As shown, the faceplate 432 may comprise a plurality of holes, and a dielectric resonator 435 may pass through each of the plurality of holes. In the illustrated embodiment, a set of six dielectric resonators 435 are shown. The resonators 435 may be arranged in a ring-like pattern. The dielectric resonators 435 may be evenly spaced around an outer region of the faceplate 432. In an embodiment, a shield 433 may be provided at a center of the faceplate 432. In the illustrated embodiment, the shield 433 is a cylindrical shield 433. Though, the shield 433 may be a ring similar to the one shown in FIG. 3A in some embodiments. In an embodiment, a gas distribution hole 434 may pass through the center of the faceplate 432 and the shield 433. An outer edge of the shield 433 may be within the ring-like pattern of the dielectric resonators 435. In some instances, an outer ring 438 may also be provided proximate to an outer edge of the faceplate 432.

In an embodiment, one or more optical ports 427 may also be provided through a thickness of the faceplate 432. Optical ports 427 may be used to enable real-time endpoint detection of etching processes within the chamber. For example, an optical sensor may be used to inspect changes in the thickness of the parasitic deposition on the susceptor. The ability to implement endpoint detection allows for greater protection to the susceptors that are being cleaned in the chamber. That is, the etching chemistry may also etch the susceptor. As such, over etching the parasitic deposition may lead to damage to the susceptor.

In the illustrated embodiment, the optical ports 427 are elongated. Elongated optical ports 427 may be beneficial for reflectometry measurements or the like. Though, some embodiments may also include optical ports 427 that are circular. Embodiments may also include a combination of elongated optical ports 427 and circular optical ports 427.

Referring now to FIG. 4B, a cross-sectional illustration of a plasma cleaning tool 420 is shown, in accordance with an embodiment. The plane of the cross-section in FIG. 4B is similar to a cross-section along the dashed line B-B′ in FIG. 4A. As shown, the chamber 421 is sealed by the lid 430 For example, the plate 431 and the faceplate 432 may seal the top opening of the chamber 421. In an embodiment, the faceplate 432 may comprise a shield 433 over the recess 402 of the susceptor 400 on the pedestal 422. In an embodiment, the outer region 403 of the susceptor 400 may be exposed to a plasma (not shown in FIG. 4B). The combination of the shield 433 and the gas distribution hole 434 allow for the segregation of the plasma over the outer region 403 of the susceptor 400.

As shown, an opening through the plate 431 may be aligned with the optical port 427 in the faceplate 432. An optical measurement assembly 445 may be provided over the optical port 427. The optical measurement assembly 445 may include a light source 446 and a detector 447. A light beam may be emitted by the light source 446 into the chamber 421 and reflected off of the susceptor 400 (or a parasitic layer on the susceptor 400) back towards the detector 447. In an embodiment, the optical measurement assembly 445 be any type of optical measurement tool that can be used to measure a thickness of a layer, a change of thickness of a layer, or the absence of a layer over the susceptor 400. For example, the optical measurement assembly 445 may be a pyrometer, a reflectometer, or the like. In an embodiment, the number of optical measurement assemblies 445 may be equal to the number of optical ports 427.

In an embodiment, the cleaning process may begin with inserting the susceptor 400 into the chamber 421. The susceptor 400 may be supported on a pedestal 422. In an embodiment, the pedestal 422 may be rotated through the cleaning process. An inert gas may be flown through the gas delivery hole 434 in order to form a positive pressure over the recess 402 of the susceptor 400. In an embodiment, a plasma may be struck over the outer regions 403 of the susceptor 400. For example, a plurality of dielectric resonators 435 (not visible in the plane of FIG. 4B) may be arranged in a ring-like pattern over the outer region 403 of the susceptor 400. Due to the positive pressure of an inert gas and the physical shield 433, the plasma is substantially prevented from forming over the recess 402 of the susceptor 400. In an embodiment, the optical measurement assembly 445 may be used to measure a thickness of the parasitic deposition on the outer region 403 of the susceptor 400. When the parasitic deposition is removed to expose a surface of the outer region 403 of the susceptor 400, the plasma cleaning process can be stopped. As such, the surface of the susceptor 400 is protected from the plasma etching process.

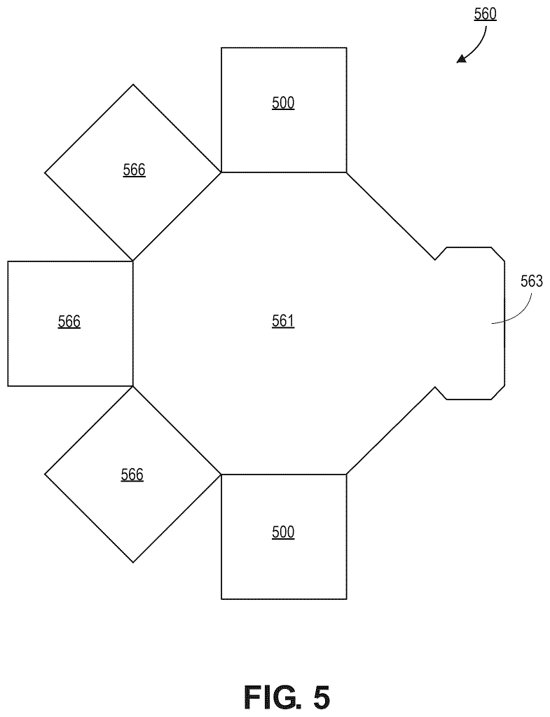

Referring now to FIG. 5, a plan view illustration of a cluster tool 560 is shown, in accordance with an embodiment. In an embodiment, the cluster tool 560 may comprise a transfer chamber 561. In an embodiment, the transfer chamber 561 may comprise one or more transfer robots. The transfer robots may be used to transfer substrates (e.g., wafers) and/or susceptors between chambers in the cluster tool 560. In an embodiment, the transfer chamber 561 may be coupled to an equipment front end module (EFEM) 563 (e.g., by one or more load locks or the like).

In an embodiment, the cluster tool 560 may comprise a plurality of chambers. For example, one or more deposition chambers 566 may be coupled to the transfer chamber 561. The deposition chambers 566 may be any suitable type of deposition chamber, such as a CVD chamber, an ALD chamber, a PVD chamber, or the like. In a particular embodiment, the deposition chambers 566 may be used to epitaxially grow a layer comprising silicon and carbon (e.g., SiC) on the substrates. As noted above, the deposition process may result in parasitic deposition on the outer edges of the susceptors used to hold the substrates during the deposition process.

In an embodiment, the cluster tool 560 may comprise one or more plasma cleaning chambers 500. The plasma cleaning chambers 500 may be used to clean the susceptors. In an embodiment, the plasma cleaning chambers 500 may be similar to any of the cleaning chambers described in greater detail herein. For example, the plasma cleaning chambers 500 may include a plurality of dielectric resonators that are arranged in a ring-like pattern around the lid of the chamber. In some embodiments, a physical shield may also be used in order to segregate the plasma to the outer regions of the susceptors.

In an embodiment, the inclusion of plasma cleaning chambers 500 in the cluster tool 560 allows for the susceptors to be transferred from the deposition chambers 566 to the cleaning chambers 500 without the need to break the vacuum. That is, the deposition chambers 566 do not need to be taken offline in order to remove the susceptors for cleaning. Further, since the susceptors can be cleaned and reused, the cost for susceptors is reduced.

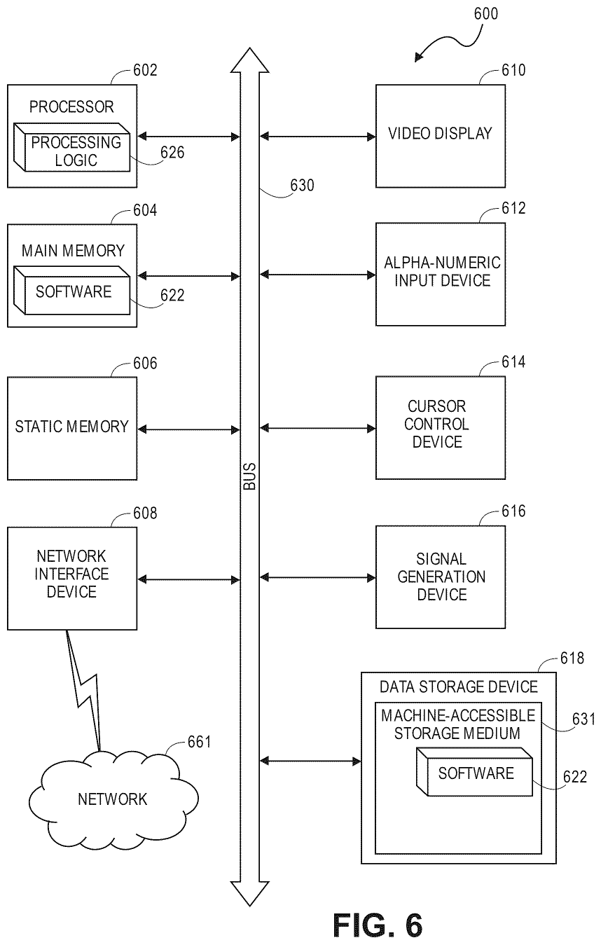

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a chamber;
a lid that is configured to seal the chamber, wherein the lid comprises:
a dielectric faceplate; and
a plurality of dielectric resonators coupled to the dielectric faceplate, wherein the plurality of dielectric resonators are arranged in a ring-like pattern; and
a gas line through the lid, wherein the gas line is within an inner perimeter of the ring-like pattern.

2. The apparatus of claim 1, further comprising:
a shield extending from the dielectric faceplate into the chamber, wherein the shield is within the inner perimeter of the ring-like pattern.

3. The apparatus of claim 2, wherein the shield is a ring.

4. The apparatus of claim 2, wherein the shield is a cylinder, and wherein the gas line passes through the cylinder.

5. The apparatus of claim 1, wherein the plurality of dielectric resonators pass through the dielectric faceplate.

6. The apparatus of claim 1, wherein the plurality of dielectric resonators are each coupled to different microwave power sources.

7. The apparatus of claim 1, further comprising:
a pedestal within the chamber, wherein the pedestal is configured to be rotated.

8. The apparatus of claim 1, further comprising:
an optical port through the lid; and
an optical measurement assembly coupled to the optical port.

9. The apparatus of claim 8, wherein the optical measurement assembly is a pyrometer or a reflectometer.

10. The apparatus of claim 1, wherein the plurality of dielectric resonators comprises six dielectric resonators that are evenly distributed about the ring-like pattern.

11. A semiconductor processing tool, comprising:
a transfer chamber;
a first chamber coupled to the transfer chamber, wherein the first chamber is configured to deposit a layer on a substrate that is supported by a susceptor; and
a second chamber coupled to the transfer chamber, wherein the second chamber is configured to clean the susceptor with a plasma that is localized over an outer region of the susceptor.

12. The semiconductor processing tool of claim 11, wherein the second chamber comprises:
a lid with a plurality of dielectric resonators arranged in a ring-like pattern;
a shield extending down from the lid, wherein the shield is within the ring-like pattern of the plurality of dielectric resonators; and
a gas line through the lid, wherein the gas line is configured to flow a purge gas into the second chamber inside of the ring-like pattern of the plurality of dielectric resonators.

13. The semiconductor processing tool of claim 12, wherein the susceptor comprises a recess for supporting the substrate, and wherein a sidewall surface of the shield is configured to be within 10 mm of an edge of the recess when a susceptor is placed in the second chamber.

14. The semiconductor processing tool of claim 12, wherein the plurality of dielectric resonators are configured to form a plasma around the shield, and wherein the purge gas is configured to reduce formation of the plasma inside the shield.

15. The semiconductor processing tool of claim 12, wherein each of the plurality of dielectric resonators are electrically coupled to different microwave power sources.

16. The semiconductor processing tool of claim 11, wherein the second chamber is configured to rotate the susceptor.

17. The semiconductor processing tool of claim 11, wherein the second chamber is configured to remove a layer comprising silicon and carbon from the susceptor.

18. A chamber lid, comprising:
a dielectric faceplate with a plurality of openings, wherein the plurality of openings are arranged in a ring-like pattern;
a shield on a surface of the dielectric faceplate, wherein the shield has an outer surface that is inside the ring-like pattern; and
a gas line that passes through the dielectric faceplate, wherein the gas line is inside an outer perimeter of the shield.

19. The chamber lid of claim 18, wherein the shield is a ring.

20. The chamber lid of claim 18, wherein the shield is a cylinder, and wherein the gas line passes through the cylinder.
